(19) United States
(12) Patent Application Publication
(10) Pub. No.: US 2025/0165670 A1
(43) Pub. Date: May 22, 2025

(54) AUTOMATIC CHECK METHOD AND DEVICE

(71) Applicant: MEDIATEK INC., Hsinchu City (TW)

(72) Inventors: Chee-Kong Ung, Hsinchu City (TW); Jung-Wen Ho, Hsinchu City (TW); Sheng-Ming Chang, Hsinchu City (TW); Ching-Chih Li, Hsinchu City (TW)

(21) Appl. No.: 18/950,423

(22) Filed: Nov. 18, 2024

Related U.S. Application Data
(60) Provisional application No. 63/599,602, filed on Nov. 16, 2023.

(51) Int. Cl. G06F 30/20

(52) U.S. Cl. CPC G06F 30/20

(57) ABSTRACT

The application provides an automatic check method and device. A schematic diagram or a layout having a plurality of elements is received. Whether the elements are classified into respective subcategories in a naming rule is determined based on keywords in the naming rule and names of the elements, wherein the naming rule comprises a plurality of main categories, each of the main categories having a plurality of subcategories, and each of the subcategories within each of the main categories having a keyword and corresponding to a predefined design rule. Incorrectly named elements that are not classified into respective subcategories are reported on a display. Fixed names of the incorrectly named elements are received.

### CROSS-REFERENCE TO RELATED ART

This application claims the benefit of U.S. Provisional patent application Ser. No. 63/599,602, filed Nov. 16, 2023, the disclosure of which is incorporated by reference herein in its entirety.

### TECHNICAL FIELD

The disclosure relates in general to an automatic check method and device, and more particularly to an automatic check method and device for automatic naming rule check, automatic schematic check and automatic layout design check based on unified naming rule and/or constraint files.

### BACKGROUND

Electronic Design Automation (EDA) refers to a category of software tools used by electronics designers to design, analyze, and simulate electronic systems and integrated circuits (ICs).

EDA is crucial for several reasons. Increased Complexity: As electronic systems and ICs become increasingly complex, manual design processes become impractical. EDA tools automate many aspects of the design process, enabling designers to handle intricate designs efficiently. Time Efficiency: EDA tools significantly reduce the time required to design electronic systems. They can automatically perform tasks that would otherwise take days or weeks to complete manually, allowing designers to focus on higher-level aspects of the design. Cost Reduction: By automating the design process and minimizing errors, EDA tools help reduce development costs. Design iterations are faster and more efficient, leading to shorter time-to-market and ultimately lower production costs. Performance Optimization: EDA tools offer various optimization algorithms to improve the performance of electronic systems. These tools can optimize factors such as power consumption, speed, area utilization, and signal integrity. Design Verification: EDA tools include powerful simulation and verification capabilities to ensure that designs meet specifications and functional requirements. They help detect errors and potential issues early in the design process, minimizing costly mistakes.

During the initial stages of designing large-scale testing platforms such as Load Boards, Probe Card Substrates, or any electronic products like PCB (printed circuit board) and Package Substrates, engineers often spend weeks manually verifying schematic connections and layout routings to adhere to design guidelines.

Currently, there is inconsistency or lack of standardization in how engineers name the various elements (nets, components, and pins) within their designs. The naming convention for nets, components, and pins is either random or inherited. “Random” refers that names are chosen arbitrarily without following any specific convention, while “inherited” suggests that names may be passed down from previous designs without careful consideration or adherence to a standardized naming scheme.

Engineers manually review both the schematic connections (how different components are connected electrically) and the layout routing (how the physical traces on the circuit board are arranged) to ensure they align with the design guidelines. This manual inspection process involves visually checking each connection and routing to catch any errors or deviations from the intended design.

Engineers may utilize EDA tools to a schematic check or layout routing check, but they must manually select the necessary nets, components, and pins for each check. This process is time-consuming and may result in oversight. That is to say, although the use of EDA tools by engineers to aid in the design process, engineers still need to manually specify which nets, components, and pins should be checked by the EDA tools for compliance with design rules and guidelines. This manual selection process can be time-consuming, as engineers must individually identify and designate the elements to be checked. Additionally, the manual nature of this process increases the risk of oversight, potentially leading to undetected errors or violations in the design. Furthermore, the schematic check result and layout routing check result are inaccurate.

Thus, in order to address the prior issues, there needs an automatic check method to reduce the workload of engineers and improve the accuracy of check results.

### SUMMARY

According to one embodiment, an automatic check method is provided. The automatic check method comprises: receiving a schematic diagram or a layout having a plurality of elements; determining whether the elements are classified into respective subcategories in a naming rule based on keywords in the naming rule and names of the elements, wherein the naming rule comprises a plurality of main categories, each of the main categories having a plurality of subcategories, and each of the subcategories within each of the main categories having a keyword and corresponding to a predefined design rule; reporting incorrectly named elements that are not classified into respective subcategories on a display, and receiving fixed names of the incorrectly named elements.

According to another embodiment, an automatic check device is provided. The automatic check device comprises: a processor; and a display coupled to the processor. The processor is configured for: receiving a schematic diagram or a layout having a plurality of elements; determining whether the elements are classified into respective subcategories in a naming rule based on keywords in the naming rule and names of the elements, wherein the naming rule comprises a plurality of main categories, each of the main categories having a plurality of subcategories, and each of the subcategories within each of the main categories having a keyword and corresponding to a predefined design rule; reporting incorrectly named elements that are not classified into respective subcategories on the display, and receiving fixed names of the incorrectly named elements.

### BRIEF DESCRIPTION OF THE DRAWINGS

FIG. 1A shows an automatic check method according to one embodiment of the application.

FIG. 1B shows an automatic check method according to one embodiment of the application.

FIG. 2 shows an example of the constraint file according to one embodiment of the application.

FIG. 3 shows an automatic naming rule check method according to one embodiment of the application.

FIG. 4 shows the automatic naming rule check result after automatic naming rule checks according to one embodiment of the application.

FIG. 5 shows an automatic schematic check method according to one embodiment of the application.

FIG. 6A to FIG. 6E shows some representative check items according to one embodiment of the application.

FIG. 7 shows an automatic layout design check method according to one embodiment of the application.

FIG. 8A to FIG. 8D shows some representative layout design check items according to one embodiment of the application.

FIG. 9 shows a block diagram of an automatic check device according to one embodiment of the application.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

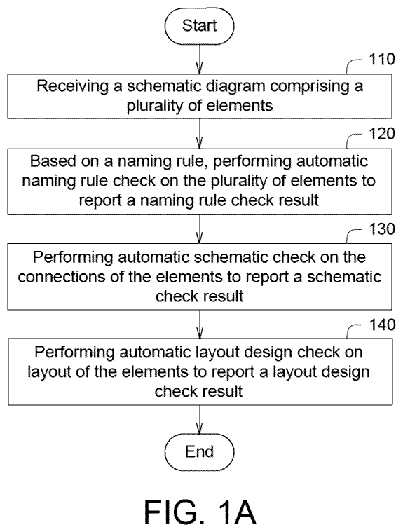

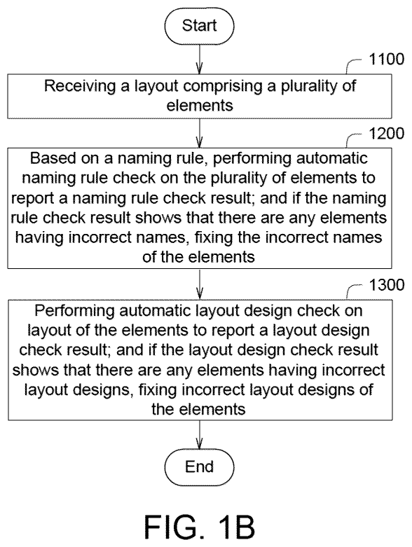

FIG. 1A shows an automatic check method according to one embodiment of the application.

In step 110, a schematic diagram is received, wherein the schematic diagram comprises a plurality of elements.

In step 120, based on a naming rule, automatic naming rule check is performed on the plurality of elements to report a naming rule check result. If the naming rule check result shows that there are any elements having incorrect names, the incorrect names of the elements are fixed.

In step 130, automatic schematic check is performed on the connections of the elements to report a schematic check result. If the schematic check result shows that there are any elements having incorrect connections, an updated schematic diagram with fixed connections is obtained.

In step 140, automatic layout design check is performed on layout of the elements to report a layout design check result. If the layout design check result shows that there are any elements having incorrect layout designs, incorrect layout designs of the elements are fixed.

FIG. 1B shows an automatic check method according to another embodiment of the application.

In step 1100, a layout is received, wherein the layout comprises a plurality of elements.

In step 1200, based on a naming rule, automatic naming rule check is performed on the plurality of elements to report a naming rule check result. If the naming rule check result shows that there are any elements having incorrect names, the incorrect names of the elements are fixed.

In step 1300, automatic layout design check is performed on layout of the elements to report a layout design check result. If the layout design check result shows that there are any elements having incorrect layout designs, incorrect layout designs of the elements are fixed.

In one embodiment of the application, the automatic check method and device implement a unified naming rule or a constraint file as an input for automatic naming rule check, automatic schematic check or automatic layout design check flows. Regarding the embodiments of the application, some ideas of the application are described below.

(1) a naming rule is defined. The naming rule comprises for example but not limited by, main categories (or said “categories”), multiple subcategories within each main category, and a specific keyword for each subcategory. The naming rule may be a unified naming rule or in a constraint file.

(2) During early design stage, element names are created manually based on the naming rule instead of random names.

(3) Optionally, keywords, and/or sub-categories and/or main categories are allowed to be added or deleted in constraint files.

(4) Automatic naming rule check is performed to show a naming rule check result, and names of elements with incorrect names are fixed manually or automatically.

(5) Automatic schematic check and automatic layout design check are performed based on the unified naming rule and/or constraint file.

(6) True violation results are reported for schematic and layout optimization. For example but not limited by, true violation results are displayed on a display apparatus of the automatic check device in one embodiment of the application.

The naming rule may be a unified naming rule or a custom naming rule. The naming rule is described in detail as follows:

### (1) Description for the Unified Naming Rule:

The unified naming rule may include main categories (e.g., “category”), multiple subcategories within each main category, and a specific keyword for each subcategory. Each subcategory has its own pre-defined design rules, which may include but are not limited to requirements for electrically connecting or coupling elements in this subcategory to other elements or to reference voltages, as well as layout constraints such as spacing limitations between elements of this subcategory and nearby elements.

Main categories include, but are not limited to, Net, Pin, and Component. For example, (i) Subcategories within the Net category include power, ground, and various types of signal categories (e.g., high-speed signal, low-speed signal); (ii) Subcategories within the Pin category include power pin, ground pin, control pin, and others; and (iii) Subcategories within the Component category comprise inductor, capacitor, resistor, etc.

### (2) Flexible Modification of the Unified Naming Rule:

The unified naming rule may be adjusted, modified or replaced based on engineers' needs. Engineers may modify the unified naming rule by adding new main categories, subcategories, keywords, etc. For instance, an engineer may input a new constraint file into a device, which could contain added main categories and/or subcategories and/or keywords. The device will then integrate contents of the new constraint file into the unified naming rule for updating the unified naming rule. Also, the engineers may cancel main categories and/or subcategories and/or keywords from the unified naming rule.

### (3) Custom Naming Rule

The engineer can provide his own constraint file containing various main categories and associated subcategories and keywords, to the device to define a custom naming rule. That is, the custom naming rule may replace the previous unified naming rule if necessary. The engineer may also update or replace the constraint file as needed.

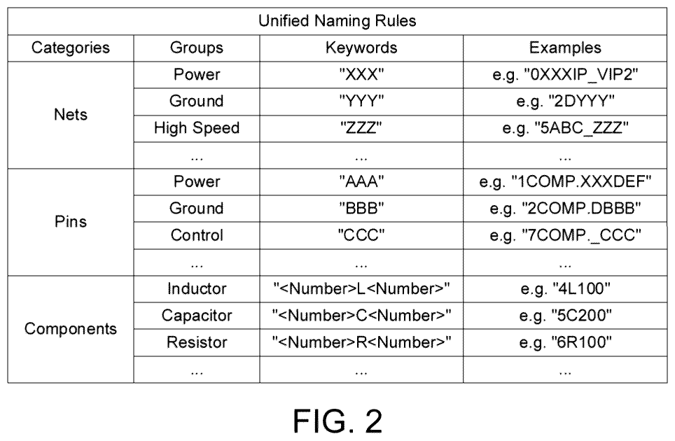

FIG. 2 shows an example of the constraint file according to one embodiment of the application. As shown in FIG. 2, (i) Subcategories within the Net category include power, ground, and various types of signal categories (e.g., high-speed signal, low-speed signal); (ii) Subcategories within the Pin category include power pin, ground pin, control pin, and others; and (iii) Subcategories within the Component category comprise inductor, capacitor, resistor, etc.

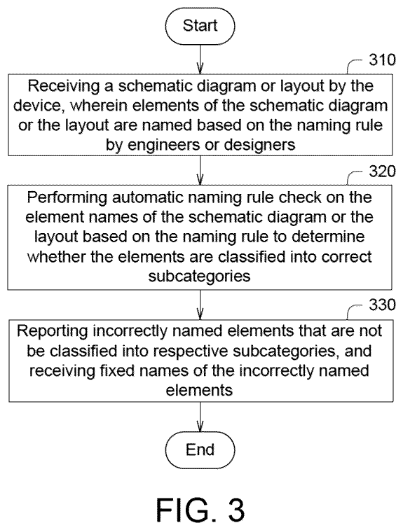

FIG. 3 shows an automatic naming rule check method according to one embodiment of the application.

In step 310, a schematic diagram or a layout is received by the device, wherein elements of the schematic diagram or the layout are named based on the naming rule by engineers or designers. The naming rule comprises a plurality of main categories, wherein each of the main categories has a plurality of subcategories, and each of the subcategories within each of the main categories has a keyword and corresponds to a predefined design rule.

In step 320, automatic naming rule check is performed on the element names of the schematic diagram or the layout based on the naming rule to determine whether the elements are classified into correct subcategories.

In step 330, incorrectly named elements that are not be classified into respective subcategories are reported, and fixed names of the incorrectly named elements are received.

In the step 330, an automatic naming rule check result is shown for fixing names of the incorrectly named elements manually by engineers until the incorrectly named elements are classified into correct subcategories.

Elements in the schematic diagram or the layout are named by the designer or through other means, following the naming rule. Upon receiving the schematic diagram or the layout, the device converts the schematic diagram or the layout to a text and identifies the main category each element should belong to based on the text. The format of the text may be a netlist format. The device determines whether the elements can be classified into respective subcategories in the identified main categories based on keywords in the naming rule and names of the elements (e.g. if the name of element comprises a keyword of a corresponding subcategory in the main category to which the element belongs, the element can be classified into the corresponding subcategory). The device then compiles statistical results of the elements and displays an error table. The error table shows elements that could not be classified into a correct subcategory. The elements that could not be classified into a correct subcategory are determined to have incorrect names. The engineer can then update or fix the names of these incorrectly named elements. Then, the device performs the automatic naming rule check on the elements with having updated or fixed until the elements are classified into correct subcategories based on the naming rule and the names of the elements.

The elements in the schematic diagram or the layout are classified into correct subcategories, enabling precise and automatic schematic check and layout design check.

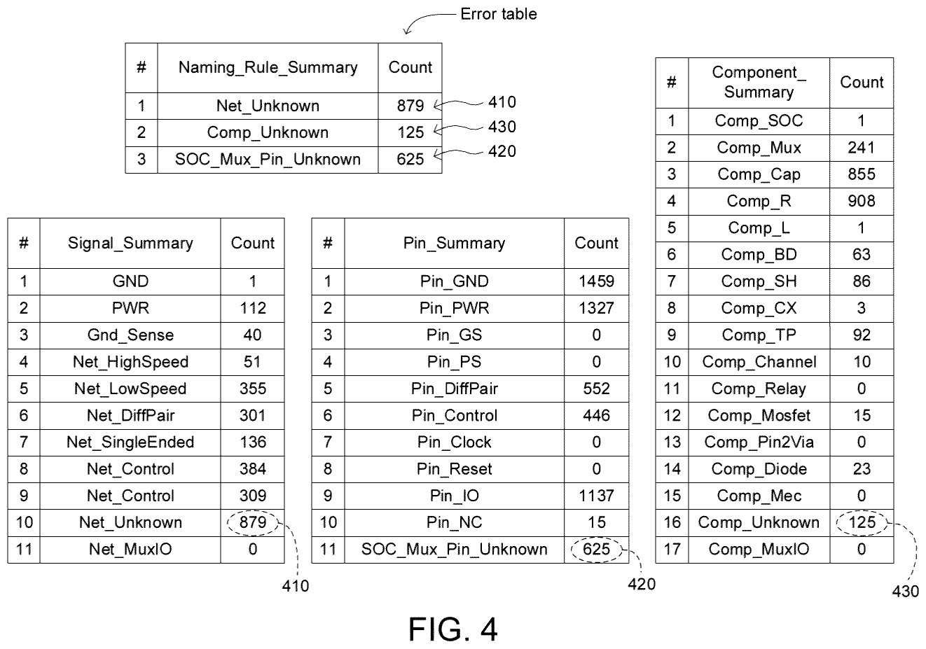

FIG. 4 shows the naming rule result after automatic naming rule checks according to one embodiment of the application. FIG. 4 shows several tables for each main category, wherein the table of the main category comprises subcategories and the count of elements in each subcategory. Additionally, FIG. 4 shows an error table that shows elements that could not be classified into a correct subcategory. Specifically, the error table comprises main categories and the count of elements with incorrect names in the corresponding main category. After engineers click on a main category within the error table or counts 410, 420 and 430 within the error table, the device displays incorrectly named elements within that main category. Engineers can then correct the names of these incorrectly named elements until these incorrectly named elements are classified into correct subcategories.

Automatic schematic checks according to one embodiment of the application are described. Based on the naming rule, automatic check logical connections of schematic netlist are developed. In an automatic schematic check of one embodiment of the application, with the naming rule, the subcategories of the main category to which the elements belong are automatically identified based on names of the elements. The automatic schematic check automatically checks whether pre-defined design rules of the subcategories to which the elements belong to are satisfied.

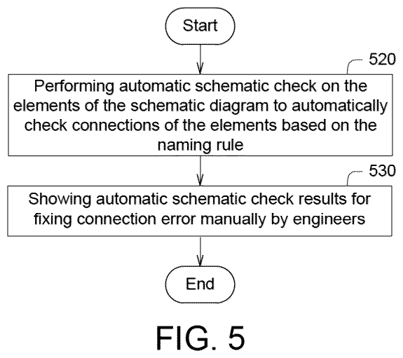

FIG. 5 shows an automatic schematic check method according to one embodiment of the application.

In step 520, automatic schematic check is performed on the elements of the schematic diagram to automatically check connections of the elements based on the naming rule, wherein the subcategory to which the element belongs is determined based on the element's name, and the determined subcategory's predefined design rule is used to check whether either the connection of the element or the relationships between the element and other elements satisfy the determined subcategory's predefined design rule.

Specifically, the device identifies the main category each element should belong to based on the text format of the schematic diagram and the device classifies each element into an appropriate subcategory in the identified main category based on the naming rule or the constraint file. With this arrangement, the subcategory to which the element belongs is determined.

In the step 520, the device may clarify the elements of the schematic diagram into respective subcategories based on the naming rule. The device performs schematic check on required sub-categories. Required sub-categories are sub-categories that require schematic checking. The required sub-categories can be selected by the engineer. With this arrangement, only the required subcategories can be checked, without having to check all elements in the main category.

In the step 520, the device may automatically check whether required subcategories of power/ground pins are connected correctly to voltage source/ground nets respectively. The device may automatically check whether required subcategories of power pins are connected correctly to capacitors. The device may automatically check whether switch component' I/O pins are connected correctly with differential pair P/N nets. The device may automatically check whether loop-back connections through multiple components (MUX, Capacitors, etc.) are correct or not and generate precise mapping tables. The device may automatically check whether device under test (DUT) pins are corrected connected to tester pins through multiple components and generates precise mapping tables.

In step 530, automatic schematic check results are shown for fixing connection error manually by engineers. If the connection of the element fails to satisfy the subcategory's predefined design rule or relationships between the element and other elements fail to satisfy the subcategory's predefined design rule, the connection of the element is incorrect. The connection of element will be corrected manually by the engineer until the subcategory's predefined design rule is satisfied.

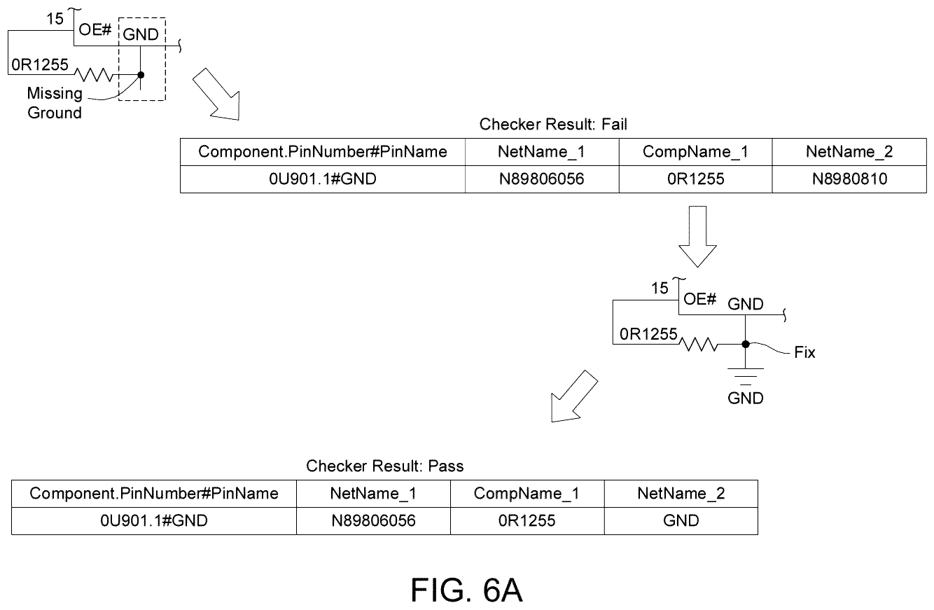

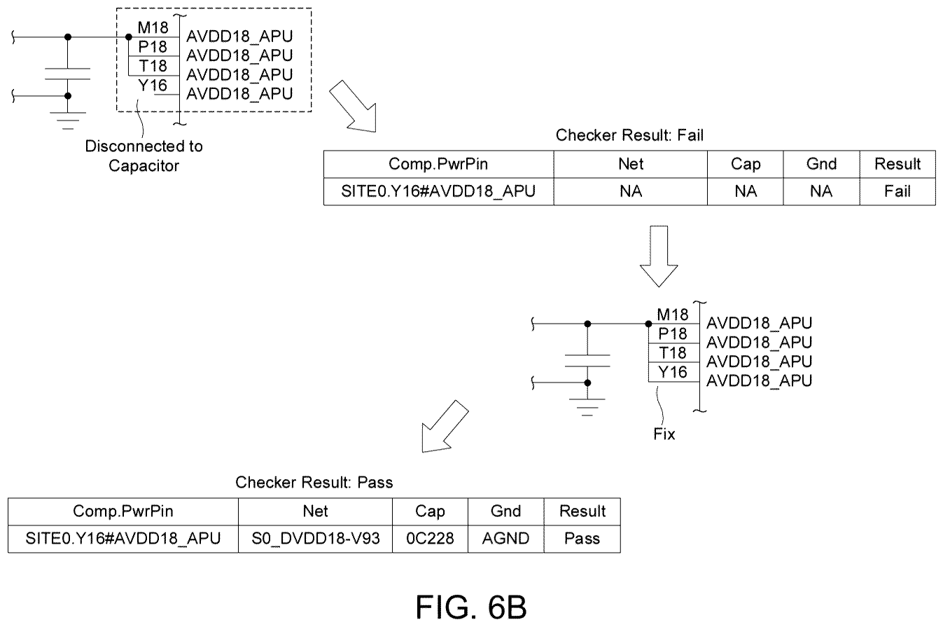

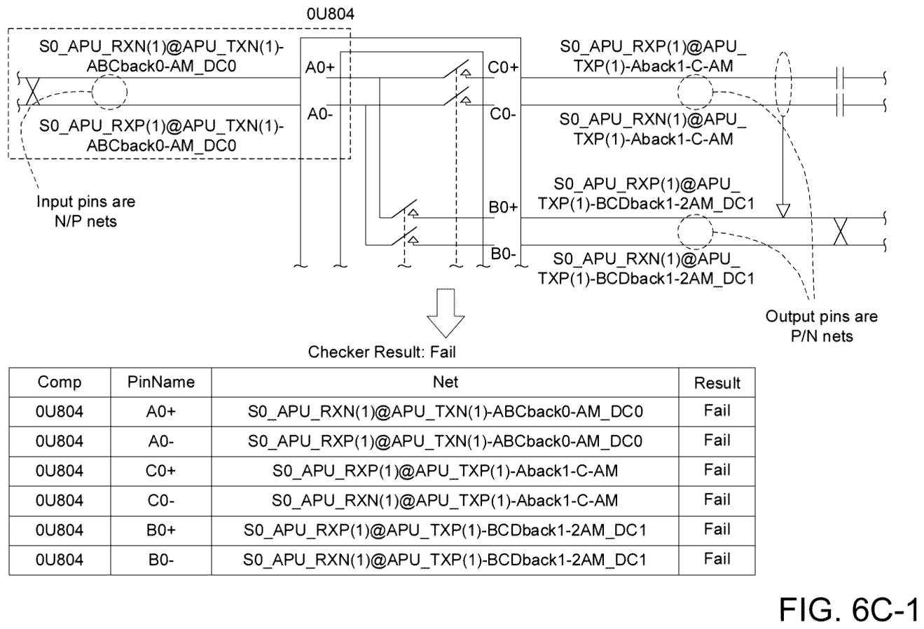

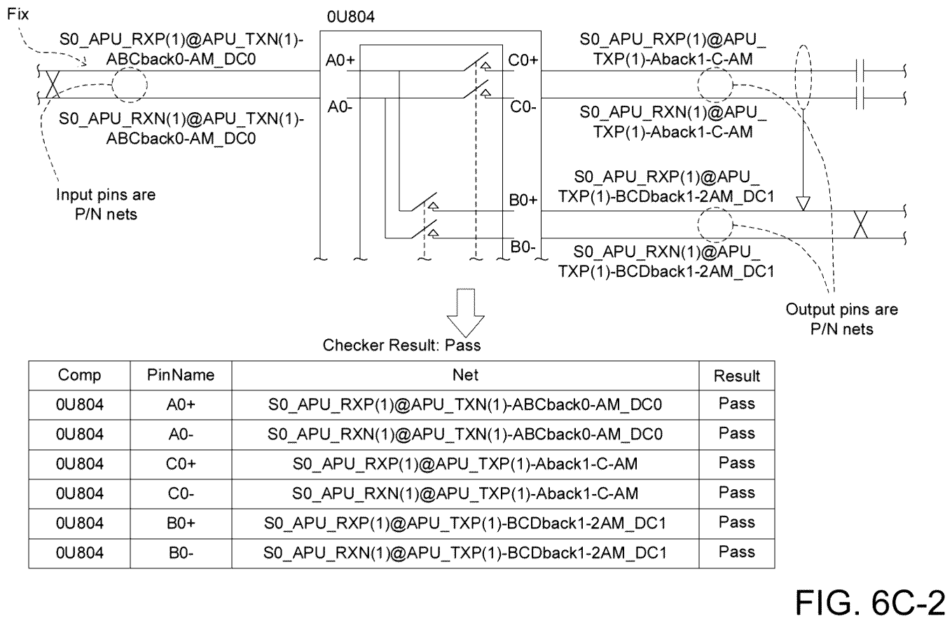

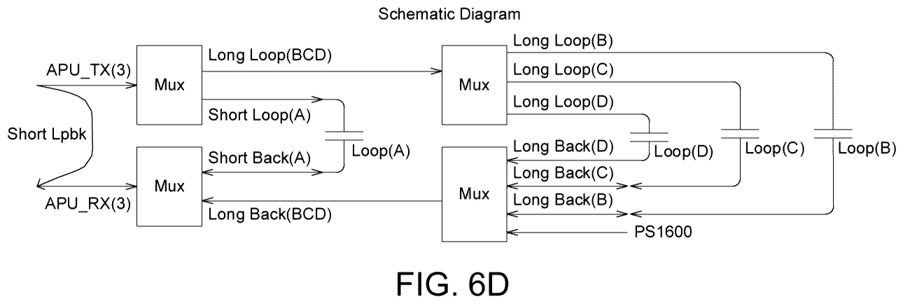

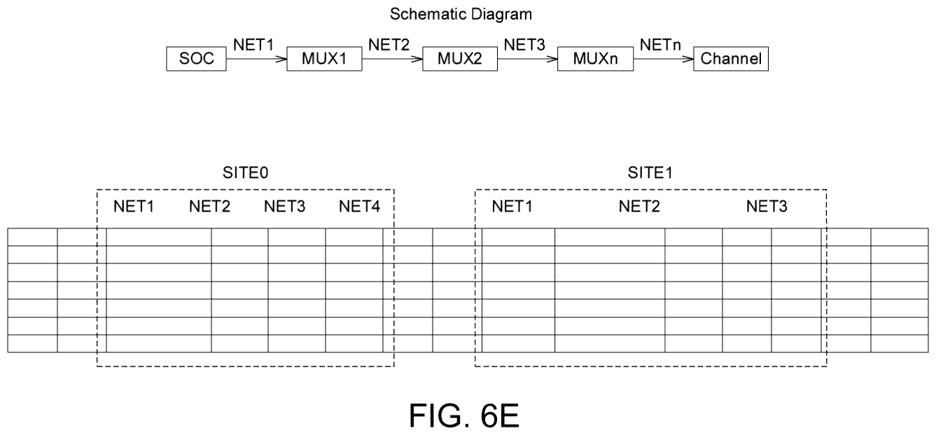

FIG. 6A to FIG. 6E shows some representative check items according to one embodiment of the application, but the application is not limited by this. By automatic check, runtime is faster and true violations are reported for quick fixes.

In FIG. 6A, the method automatically determines that the element belongs to the Ground subcategory within the main category “Pin” based on the PinName (i.e. name of the element). According to the predefined design rule for the pin in the Ground subcategory, the design rule requires that the pin in the Ground subcategory should be connected to an element in GND subcategory in main category “Net”. Thus, the method automatically checks whether the pin is connected correctly to the element in GND subcategory in main category “Net” or not. If a connection error of the pin is checked, the error may be fixed manually by the engineer and the automatic schematic check is performed again to make sure whether there is no connection error.

In FIG. 6B, the method automatically determine that the element belongs to the power pin subcategory within the main category “pin” based on the PinName (i.e. name of the element). According to the predefined design rules for the pin in the power pin subcategory, the pin in the power subcategory should be connected to a capacitor. The method checks whether the pin is connected correctly to capacitor. If a connection error of the pin is checked, the error may be fixed manually by the engineer and the automatic schematic check is performed again to make sure whether there is no connection error.

In FIG. 6C-1 and FIG. 6C-2, the method automatically determines that the I/O ports A0+/A0−, B0+/B0−, and C0+/C0− of the switch component belong to the differential pins subcategory within the main category “pin” based on their PinName. The predefined design rules for differential pins requires that A0+, B0+, and C0+ pins should connect to signals indicating the same polarity, such as positive, and A0−, B0−, and C0− should connect to signals indicating the same polarity, such as negative. The method automatically checks whether the switch component's I/O ports A0+/A0−, B0+/B0−, and C0+/C0− are correctly connected to correct signals. If connection errors are checked, errors may be fixed manually by the engineer and the automatic schematic check is performed again to make sure whether there is no connection error.

In FIG. 6D, with the unified naming rule and/or constraint file, the method may automatically check whether loop-back connections through multiple components (MUX, Capacitors, etc.) are correct or not and generate precise mapping tables. If loop connection errors are checked, errors may be fixed and the automatic schematic check is performed again to make sure whether there is no connection error. The method automatically determines that the pin “APU_TX(3)” belongs to the high-speed signal pin subcategory within the main category “pin” based on the PinName. The method checks whether that the connections of the pin “APU_TX(3)” are correct according to the pre-defined design rules of the high-speed signal pin subcategory within the main category “pin”. If connection errors of the pin “APU_TX(3)” are checked, errors may be fixed manually by the engineer and the automatic schematic check is performed again to make sure whether there is no connection error. By so, human mistakes are prevented.

In FIG. 6E, the method automatically checks whether DUT pins are corrected connected to tester pins through multiple components (MUX, Capacitors, etc.) and generates precise mapping tables. The method determines the subcategory to which the DUT pin's name belongs based on the DUT pin's name, the subcategory to which the MUX pin's name belongs based on the MUX pin's name, and the subcategory to which the name of the signal between the MUX pin and the DUT pin or two DUT pins belongs based on the name of the signal. The method checks whether DUT pins and DUT pins are correctly connected based on the predefined design rules of determined subcategories. If connection errors are checked, errors may be fixed manually by the engineer and the automatic schematic check is performed again to make sure whether there is no connection error. By so, human mistakes are prevented.

Automatic layout design checks according to one embodiment of the application are described.

In one embodiment of the application, layout routings are automatically checked based on design guidelines. Automatic layout design checks can be re-used for various layout designs based on product lines. In an automatic layout design check of one embodiment of the application, with the unified naming rule or constraint file, the subcategories of the main category to which the elements belong are automatically identified based on names of the elements; and based on the pre-defined design rule of the identified subcategory, whether layout of the element satisfies the pre-defined design rule of the identified subcategory is determined. If a layout error is found, layout of the element is corrected until layout of the element satisfies the pre-defined design rule of the identified subcategory.

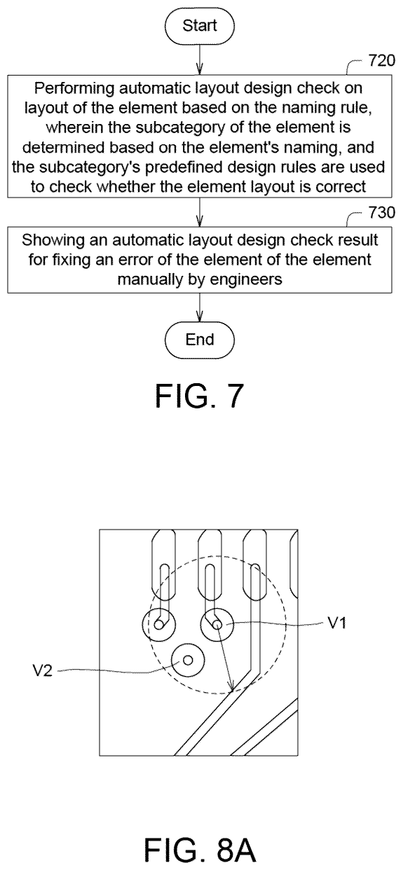

FIG. 7 shows an automatic layout design check method according to one embodiment of the application.

In step 720, automatic layout design check is performed on layout of the element based on the naming rule, wherein the subcategory of the element is determined based on the element's naming, and the subcategory's predefined design rules are used to check whether the element layout is correct.

In the step 720, the device may clarify the elements of the layout into respective subcategories based on the naming rule. The device performs layout design check on required sub-categories. Required sub-categories are sub-categories that require layout design checking. The required sub-categories can be selected by the engineer. With this arrangement, only the required subcategories can be checked, without having to check all elements in the main category.

In this step, the device may automatically check whether there is a grounding via V1 within a specified radius of the high-speed signal via V2. The device may automatically check whether a spacing between signal traces in required signal trace subcategories meets a requirement. The device may automatically check whether a resistance from a required start point to an end point through at least one component in the layout meets a requirement. The device may automatically check a KOZ (keep-out-zone) of required components in the layout.

In step 730, an automatic layout design check result is shown for fixing an error of the element (e.g., a design rule error of the element) manually by engineers.

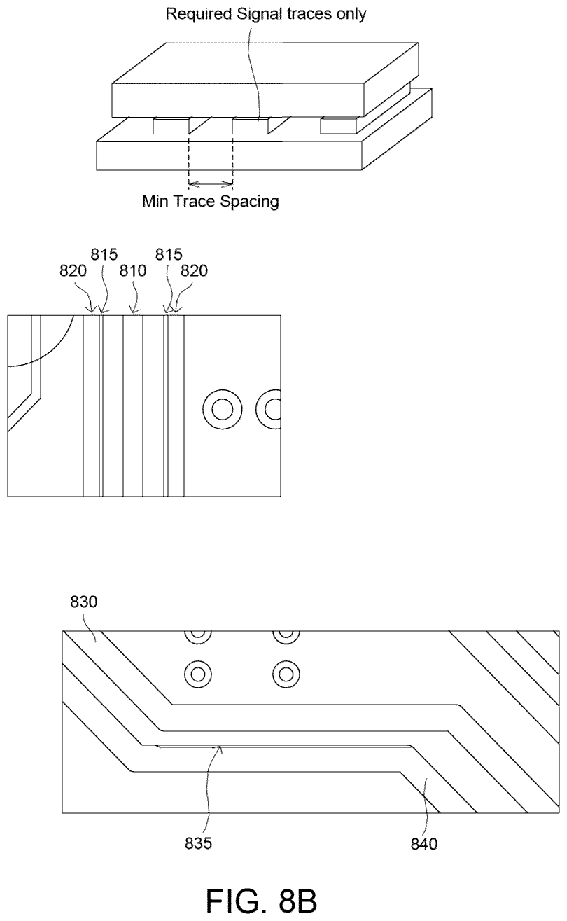

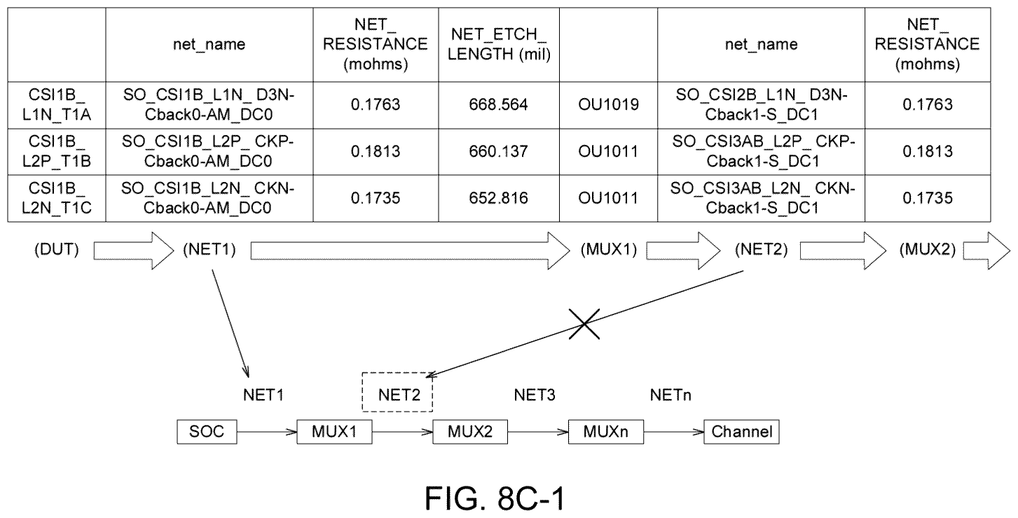

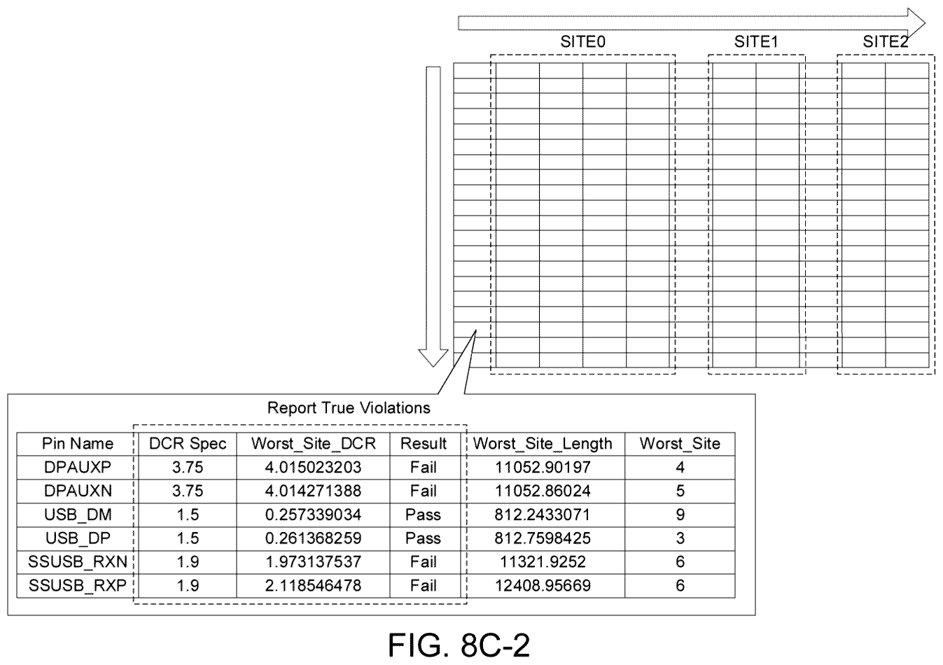

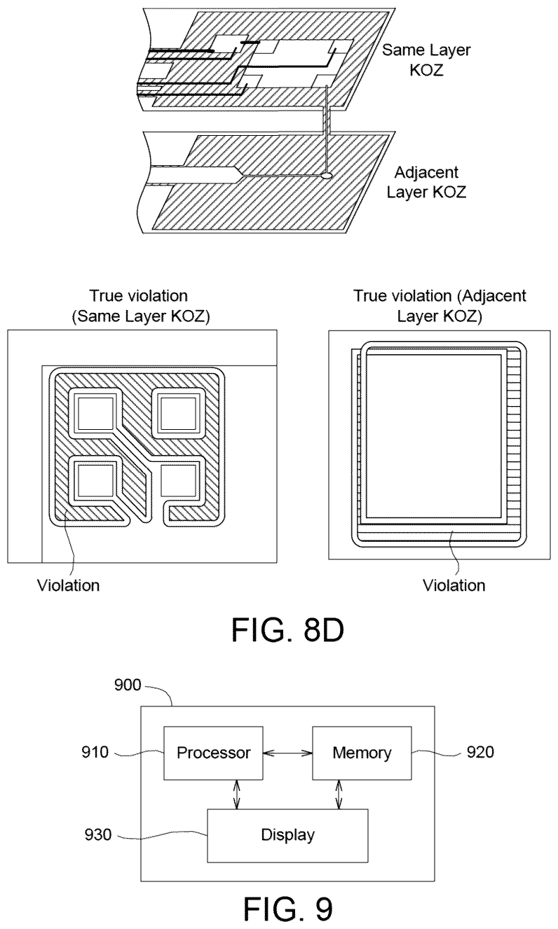

FIG. 8A to FIG. 8D show some representative layout design check items according to one embodiment of the application, but the application is not limited by this. By automatic check, runtime is faster and true violations are reported for quick fixes.

Elements in the schematic diagram correspond to elements in the layout, for example, a signal element in the schematic diagram corresponds to a trace or via in the layout. As in FIG. 8A, in one possible example, the automatic layout design check method automatically identifies that the via in the layout corresponds to a first element of the schematic, wherein the first element is classified into the high-speed signal subcategory within the main category “net” based on the first element name. The predefined design rule for high-speed signals subcategory may specify that a grounding via must be within a defined radius of a high-speed signal via. The method checks whether there is a grounding via V1 within the specified radius of the high-speed signal via V2. By so, errors may be fixed manually by the engineer and the automatic layout design check is performed again to make sure whether there is no design rule error.

In FIG. 8B, the automatic layout design check method automatically determines the subcategory of the element based on the element's names, and the subcategory's predefined design rule is used to check whether the element layout is correct. For example, as shown in FIG. 8B, the spacing between the signal traces 810 and 820 is smaller than the minimum spacing, which violates the predefined design rule of the subcategory of the signal traces 810 and 820, and a true violation warning 815 is flagged. Similarly, the spacing between the signal traces 830 and 840 is smaller than the minimum spacing, which violates the predefined design rule of the subcategory of the signal traces 830 and 840, and a true violation warning 835 is flagged. By so, errors may be fixed manually by the engineer and the automatic layout design check is performed again to make sure whether there is no design rule error.

In FIG. 8C-1 and FIG. 8C-2, the automatic layout design check method automatically determines the subcategory of the element based on the element's name, and the subcategory's predefined design rule is used to check whether the element layout is correct. For example, the predefined design rule of the subcategory requires that a resistance from a required start point to an end point (e.g. DUT pins to tester pins) through at least one component (MUX, Relay, Resistor, etc.) in layout must satisfy a resistance requirement. When the resistance from the required start point to the end point through at least one component in layout does not satisfy the resistance requirement, a true violation is flagged. In response to the true violation, the resistance in layout is adjusted manually or automatically until the resistance requirement is met. By so, errors may be fixed manually by engineers and the automatic layout design check is performed again to make sure whether there is no design rule error.

In FIG. 8D, the automatic layout design check method automatically determines the specific component subcategory of the component category based on the element name and then checks for any nets that violate the predefined design rule for that specific component subcategory (i.e., there should be no other nets except the net connected to the element within the reserved area to prevent interference with the component's signal). In circuit design layout, a Keep-Out Zone (KOZ) refers to an area on a printed circuit board (PCB) where components or traces are not allowed. In one embodiment of the application, if the predefined design rule for that specific component subcategory is violated, a true violation is flagged. In response to the true violation, any other nets except the net connected to the element inside the KOZ (keep-out-zone) are removed manually by the engineer until KOZ requirement is met. FIG. 8D shows that whether KOZ on the same layer and KOZ on the adjacent layer are met or not based on the design rule for the subcategory. By so, errors may be fixed manually by the engineer and the automatic layout design check is performed again to make sure whether there is no design rule error.

FIG. 9 shows a block diagram of an automatic check device according to one embodiment of the application. The automatic check device 900 includes a processor 910, a memory 920 and a display 930. The processor 910 is coupled to the memory 920 and the display 930. The memory 920 is used for storing the constraint file or the unified naming rule. The display 930 is used to display the check results. The processor 910 is used to perform the above automatic check method of according to one embodiment of the application.

The processor 910 could be, for example, implemented by a chip, a circuit block in the chip, a firmware circuit, a circuit board having several electronic elements and wires.

The automatic check method and device according to one embodiment of the application have several advantages compared to prior arts. For example but not limited by, the automatic check method and device according to one embodiment of the application has the following advantages: (1) re-usable the unified naming rule or constraint file for various schematic and layout designs; (2) more precise results than EDA methods; (3) saving human efforts; (4) expandable to develop more automatic check items for better coverage in future.

In one embodiment of the application, engineers follow a naming rule (the unified naming rule or constraint file). Thus, engineers may adhere to the naming rule for nets, components, and pins within a schematic diagram. The device can automatically classify the elements in the schematic diagram or in the layout into a correct subcategory.

The foregoing mainly describes the solutions provided in the embodiments of the application. It may be understood that, to implement the foregoing functions, the automatic check device includes corresponding hardware structures and/or software modules for performing the functions. A person skilled in the art should easily be aware that, in combination with units and algorithm steps of the examples described in the embodiments disclosed in this specification, this application may be implemented in a hardware form or in a form of combining hardware with computer software. Whether a function is performed by hardware or hardware driven by computer software depends on particular applications and design constraints of the technical solutions. A person skilled in the art may use different methods to implement the described functions for each particular application, but it should not be considered that the implementation goes beyond the scope of this application.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. An automatic check method performed by a processor, comprising:
receiving a schematic diagram or a layout having a plurality of elements;
determining whether the elements are classified into respective subcategories in a naming rule based on keywords in the naming rule and names of the elements, wherein the naming rule comprises a plurality of main categories, each of the main categories having a plurality of subcategories, and each of the subcategories within each of the main categories having a keyword and corresponding to a predefined design rule;
reporting incorrectly named elements that are not classified into respective subcategories; and
receiving fixed names of the incorrectly named elements.

2. The automatic check method according to claim 1, the step of determining whether the elements are classified into respective subcategories in the naming rule based on the keywords in the naming rule and names of the elements comprises:
determining respective main categories of the elements based on a text converted from the schematic diagram or the layout; and
determining whether the elements are classified into respective subcategories in the determined main categories based on keywords in the naming rule and names of the elements.

3. The automatic check method according to claim 1, wherein
the naming rule is adjusted or modified by adding or cancelling at least one of the main categories, the subcategories and the keywords.

4. The automatic check method according to claim 1, wherein the naming rule is a unified naming rule applicable to a plurality of schematic diagrams.

5. The automatic check method according to claim 1, wherein
the naming rule is inputted in a constraint file containing the main categories, subcategories associated with each main category, and a keyword corresponding to each subcategory.

6. The automatic check method according to claim 5, wherein different schematic diagrams correspond to different constraint files.

7. The automatic check method according to claim 1, further comprising:
performing an automatic schematic check on connections of the elements based on the predefined design rules of the subcategories of the elements to generate a schematic check result; and
in response that the schematic check result indicating that the connections of the elements fail to satisfy the predefined design rules of the subcategories, the connections of the elements are corrected until the predefined design rules of the subcategories are satisfied.

8. The automatic check method according to claim 7, wherein the step of performing an automatic schematic check on connections of the elements based on the predefined design rules of the subcategories of the elements comprises:
clarifying the elements into respective subcategories based on the naming rule; and
performing the automatic schematic check on required subcategories, wherein required subcategories are subcategories that require schematic checking.

9. The automatic check method according to claim 7, wherein the plurality of elements comprise a first element and a second element, and the first element is a pin, and the second element is a signal connected the pin;
the step of performing an automatic schematic check on connections of the elements based on the predefined design rules of the subcategories of the elements comprises:
determining a first subcategory to which the pin belongs based on a name of the pin;
determining a second subcategory to which the signal belongs based on a name of the signal; and
determining whether the connection from the pin to the signal based on a predefined design rule corresponding to the first subcategory and a predefined design rule corresponding to the second subcategory.

10. The automatic check method according to claim 7, wherein
the plurality of elements comprise differential input pins of a switching element and differential output pins of the switching element, differential input pins comprise a positive input pin and a negative input pin, and differential output pins comprise a positive output pin and a negative output pin;
the differential input pins and differential output pins belong to a differential pin subcategory within a main category pin;
the predefined design rules of the subcategories of the elements comprises: the positive input pin in the differential input pins and the positive output pin in differential output pins should connect to signals indicating the same polarity, and the negative input pin in the differential input pins and the negative output pin in differential output pins should connect to signals indicating the same polarity.

11. The automatic check method according to claim 1, further comprising:
performing an automatic layout design check on layout of the elements based on the predefined design rules of the subcategories of the elements to generate a layout design check result; and
in response that the layout design check result indicating the layout of the elements fail to satisfy the predefined design rules of the subcategories, layouts of the elements are corrected until layout of the elements satisfies the predefined design rules of the subcategories.

12. The automatic check method according to claim 11, the step of performing an automatic layout design check on layout of the elements based on the predefined design rules of the subcategories of the elements to generate a layout design check result comprises:
clarifying the elements into respective subcategories based on the naming rule; and
performing the automatic layout design check on required subcategories, wherein required subcategories are subcategories that require schematic checking.

13. An automatic check device comprising:
a processor; and
a display coupled to the processor;
wherein the processor is configured for:
receiving a schematic diagram or a layout having a plurality of elements;
determining whether the elements are classified into respective subcategories in a naming rule based on keywords in the naming rule and names of the elements, wherein the naming rule comprises a plurality of main categories, each of the main categories having a plurality of subcategories, and each of the subcategories within each of the main categories having a keyword and corresponding to a predefined design rule;
reporting incorrectly named elements that are not classified into respective subcategories on the display; and
receiving fixed names of the incorrectly named elements.

14. The automatic check device according to claim 13, wherein in determining whether the elements are classified into respective subcategories in the naming rule based on the keywords in the naming rule and the names of the elements, the processor is further configured for:
determining respective main categories of the elements based on a text converted from the schematic diagram or the layout; and
determining whether the elements are classified into respective subcategories in the determined main categories based on keywords in the naming rule and names of the elements.

15. The automatic check device according to claim 13, wherein the processor is further configured for:
adjusting or modifying the naming rule by adding or cancelling at least one of the main categories, the subcategories and the keywords.

16. The automatic check device according to claim 13, wherein the naming rule is inputted in a constraint file containing the main categories, subcategories associated with each main category, and a keyword corresponding to each subcategory.

17. The automatic check device according to claim 13, wherein the processor is further configured for:
performing an automatic schematic check on connections of the elements based on the predefined design rules of the subcategories of the elements to generate a schematic check result; and
in response that the schematic check result indicating that the connections of the elements fail to satisfy the predefined design rules of the subcategories, the connections of the elements are corrected until the predefined design rules of the subcategories are satisfied.

18. The automatic check device according to claim 17, wherein in performing an automatic schematic check on connections of the elements, the processor is further configured for: clarifying the elements into respective subcategories based on the naming rule; and performing the automatic schematic check on required subcategories, wherein required subcategories are subcategories that require schematic checking.

19. The automatic check device according to claim 13, wherein the processor is further configured for:
performing an automatic layout design check on layout of the elements based on the predefined design rules of the subcategories of the elements to generate a layout design check result; and
in response that the layout design check result indicating the layout of the elements fail to satisfy the predefined design rules of the subcategories, correcting layouts of the elements until layout of the elements satisfies the predefined design rules of the subcategories.

20. The automatic check device according to claim 19, wherein in performing an automatic layout design check on layout of the elements, the processor is further configured for: clarifying the elements into respective subcategories based on the naming rule; and performing the automatic layout design check on required subcategories, wherein required subcategories are subcategories that require schematic checking.
